(19) United States
(12) Patent Application Publication
(10) Pub. No.: US 2024/0334717 A1
(43) Pub. Date: Oct. 3, 2024

(54) METHODS OF FORMING MICROELECTRONIC DEVICES, AND RELATED MICROELECTRONIC DEVICES, MEMORY DEVICES, AND ELECTRONIC SYSTEMS

(71) Applicant: Micron Technology, Inc., Boise, ID (US)

(72) Inventors: Kunal R. Parekh, Boise, ID (US); Russell L. Meyer, Boise, ID (US)

(21) Appl. No.: 18/424,713

(22) Filed: Jan. 26, 2024

Related U.S. Application Data
(60) Provisional application No. 63/493,176, filed on Mar. 30, 2023.

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2924/1431; H01L 2924/14511

(57) ABSTRACT

A method of forming a microelectronic device includes forming a first assembly including a semiconductor base structure, a first circuitry region including first devices at a first boundary of the semiconductor base structure, and a second circuitry region including second devices at a second boundary of the semiconductor base structure vertically offset from the first boundary. A microelectronic device structure is formed and includes a stack structure including tiers individually including conductive material and insulative material vertically adjacent the conductive material, and cell pillar structures including semiconductor material vertically extending through the stack structure. The first assembly is attached to the microelectronic device structure to form a second assembly. Microelectronic devices, memory devices, and electronic systems are also described.

### CROSS-REFERENCE TO RELATED APPLICATION

This application claims the benefit under 35 U.S.C. § 119(e) of U.S. Provisional Patent Application Ser. No. 63/493,176, filed Mar. 30, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified, easier and less expensive to fabricate designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in one or more decks (e.g., stack structures) including tiers of conductive structures and dielectric materials. Each vertical memory string may include at least one select device coupled in series to a serial combination of vertically stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Control logic devices within a base control logic structure underlying a memory array of a memory device (e.g., a non-volatile memory device) have been used to control operations (e.g., access operations, read operations, write operations) on the memory cells of the memory device. An assembly of the control logic devices may be provided in electrical communication with the memory cells of the memory array by way of routing and interconnect structures. However, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of a memory device, and/or improvements in the performance (e.g., faster memory cell ON/OFF speed, lower threshold switching voltage).

### BRIEF DESCRIPTION OF THE DRAWINGS

FIGS. 1A through 1F are simplified, partial longitudinal cross-sectional views illustrating different processing stages of a method of forming a microelectronic device, in accordance with embodiments of the disclosure.

FIG. 2 is a schematic block diagram of an electronic system, in accordance with an embodiment of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details.

Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein, the terms “configured” and “configuration” refers to a size, a shape, a material composition, a material distribution, orientation, and arrangement of at least one feature (e.g., one or more of at least one structure, at least one material, at least one region, at least one device) facilitating use of the at least one feature in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., structures, materials, regions, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga₁₋ₓAs), and quaternary compound semiconductor materials (e.g., Ga_{X}In_{1-X}As_{Y}P_{1-y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

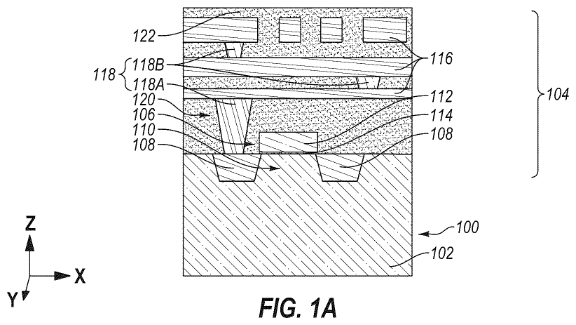

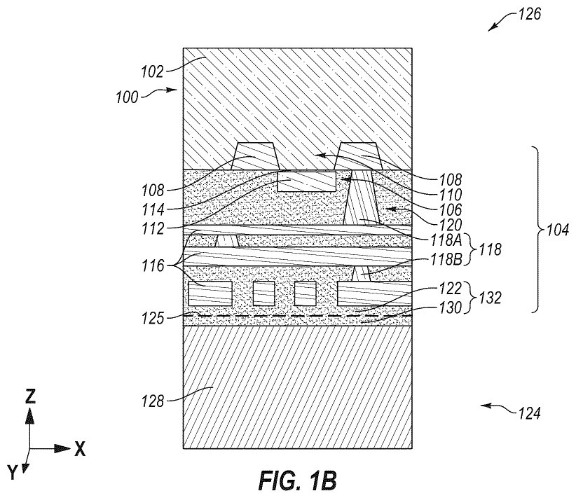

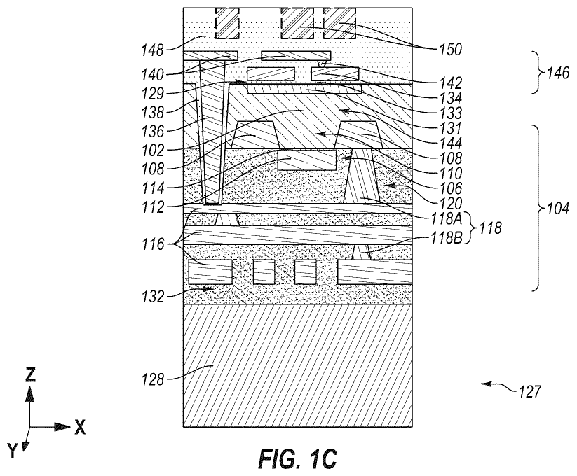

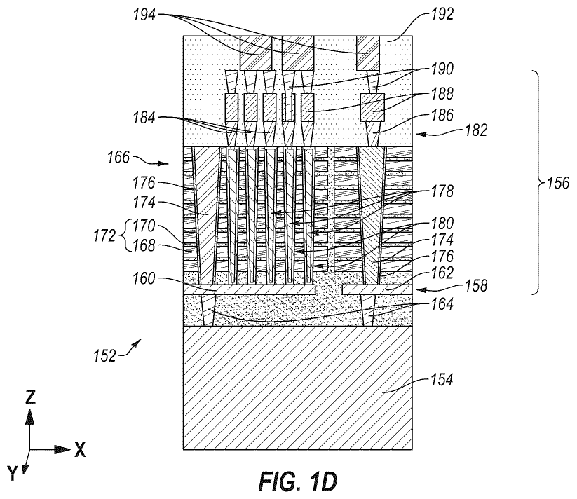

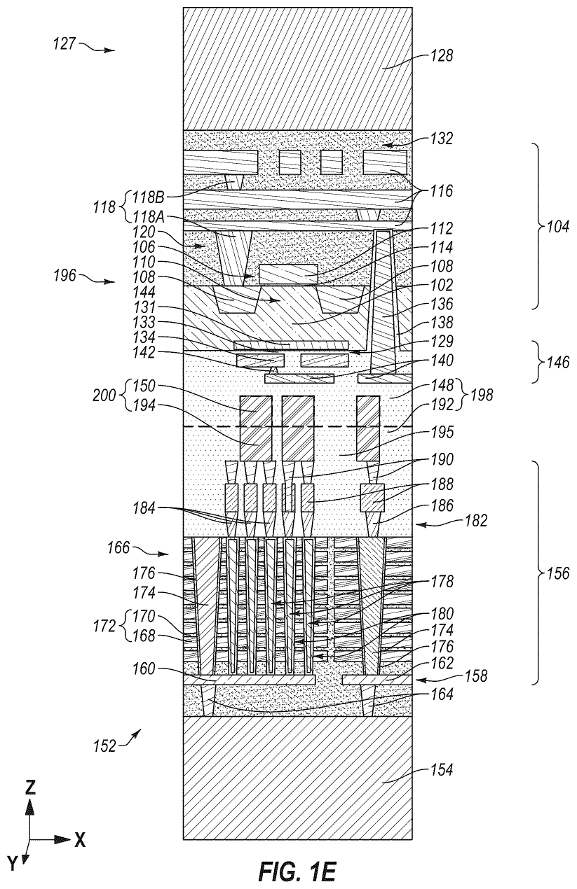

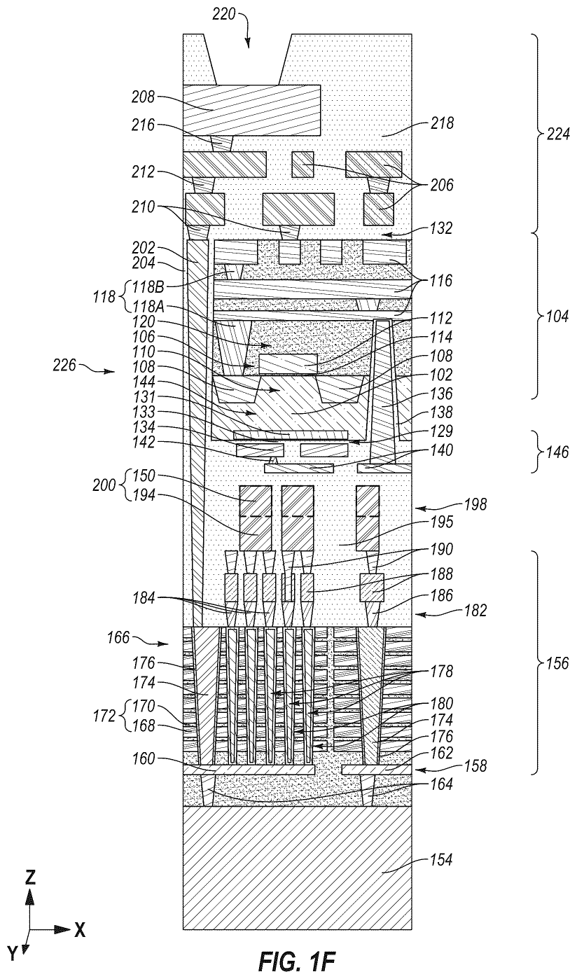

FIGS. 1A through 1F are simplified, partial cross-sectional views illustrating different processing stages of a method of forming a microelectronic device (e.g., a memory device, such as a 3D NAND Flash memory device), in accordance with embodiments of the disclosure. With the description provided below, it will be readily apparent to one of ordinary skill in the art that the methods and structures described herein may be used to form various devices and electronic systems.

Referring to FIG. 1A, a first microelectronic device structure 100 may be formed to include a first base structure 102, and a first circuitry region 104 (e.g., a control circuitry region) at least partially overlying the first base structure 102. The first circuitry region 104 may be positioned at a front side of the first base structure 102, and may thus be considered a front side circuitry region relative to first base structure 102. As described in further detail below, an additional (e.g., second) circuitry region may be formed at a back side of the first base structure 102, and may thus be considered a backside circuitry region relative to first base structure 102. The first circuitry region 104 may include transistors 106, first routing structures 116, first contact structures 118, and a first isolation material 122. The first circuitry region 104 of the first microelectronic device structure 100 may employed within a microelectronic device (e.g., a memory device, such as a 3D NAND Flash memory device) to subsequently be formed using the first microelectronic device structure 100 and at least one additional microelectronic device structure, as described in further detail below. The transistors 106, the first routing structures 116, and the first contact structures 118 of the first microelectronic device structure 100 may form circuitries (e.g., control logic circuities) of various first devices 120 of the first circuitry region 104, as also described in further detail below.

The first base structure 102 of the first microelectronic device structure 100 includes a base material or construction upon which additional features (e.g., materials, structures, devices) of the first microelectronic device structure 100 are formed. The first base structure 102 may comprise a semiconductor structure (e.g., a semiconductor wafer), or a base semiconductor material on a supporting structure. For example, the first base structure 102 may comprise a conventional silicon substrate (e.g., a conventional silicon wafer), or another bulk substrate comprising a semiconductor material. In some embodiments, the first base structure 102 comprises a silicon wafer. In addition, the first base structure 102 may include one or more layers, structures, and/or regions formed therein and/or thereon. For example, the first base structure 102 may include conductively doped regions and undoped regions.

The transistors 106 of the first circuitry region 104 may be formed to vertically intervene between portions of the first base structure 102 and the first routing structures 116 of the first circuitry region 104. An individual transistor 106 may be formed to include conductively doped regions 108 (e.g., serving as source regions and drain regions of the transistors 106) within the first base structure 102, a channel region 110 within the first base structure 102 and horizontally interposed between the conductively doped regions 108, a gate structure 112 (e.g., a gate electrode) vertically overlying the channel region 110, and gate dielectric material 114 vertically interposed between (e.g., in the Z-direction) and horizontally overlapping (e.g., in the X-direction, in the Y-direction) the channel region 110 and the gate structure 112.

For an individual transistor 106 of the first circuitry region 104, the conductively doped regions 108 thereof within the first base structure 102 may be doped with one or more desirable dopants (e.g., chemical species). In some embodiments, the conductively doped regions 108 of an individual transistor 106 are doped with at least one N-type dopant (e.g., one or more of phosphorus, arsenic, antimony, and bismuth). In some of such embodiments, the channel region 110 of the transistor 106 is doped with at least one P-type dopant (e.g., one or more of boron, aluminum, and gallium). In some other of such embodiments, the channel region 110 of the transistor 106 is substantially undoped. In additional embodiments, the conductively doped regions 108 of an individual transistor 106 are doped with at least one P-type dopant (e.g., one or more of boron, aluminum, and gallium). In some of such additional embodiments, the channel region 110 of the transistor 106 is doped with at least one N-type dopant (e.g., one or more of phosphorus, arsenic, antimony, and bismuth). In some other of such additional embodiments, channel region 110 of the transistor 106 is substantially undoped.

The gate structures 112 may individually horizontally extend (e.g., in the Y-direction) between and be employed by multiple transistors 106 of the first circuitry region 104. The gate structures 112 may be formed of and include conductive material. By way of non-limiting example, the gate structures 112 may be formed of and include one or more of at least one metal, at least one alloy, and at least one conductive metal-containing material (e.g., a conductive metal nitride, a conductive metal silicide, a conductive metal carbide, a conductive metal oxide). The gate structures 112 may individually be substantially homogeneous, or the gate structures 112 may individually be heterogeneous.

The gate dielectric material 114 may be formed of and include dielectric material, such as dielectric oxide material (e.g., silicon oxide). In some embodiments, the gate dielectric material 114 is formed of and includes silicon dioxide (SiO₂).

The first routing structures 116 may vertically overlie (e.g., in the Z-direction) the first base structure 102, and may be electrically connected to at least some of the transistors 106. The first routing structures 116 may serve as local routing structures for a microelectronic device to subsequently be formed using the first microelectronic device structure 100 and at least one additional microelectronic device structure. A first group 118A of the first contact structures 118 may vertically extend between and couple at least some of the transistors 106 to one or more of the first routing structures 116. In addition, a second group 118B of the first contact structures 118 may vertically extend between and couple some of the first routing structures 116 to one another.

The first routing structures 116 may each individually be formed of and include conductive material. By way of non-limiting example, the first routing structures 116 may be formed of and include one or more of at least one metal, at least one alloy, and at least one conductive metal-containing material (e.g., a conductive metal nitride, a conductive metal silicide, a conductive metal carbide, a conductive metal oxide). In some embodiments, the first routing structures 116 are individually formed of and include Cu. In additional embodiments, the first routing structures 116 are individually formed of and include W.

The first contact structures 118 (including the first group 118A and the second group 118B thereof) may each individually be formed of and include conductive material. By way of non-limiting example, the first routing structures 116 may be formed of and include one or more of at least one metal, at least one alloy, and at least one conductive metal-containing material (e.g., a conductive metal nitride, a conductive metal silicide, a conductive metal carbide, a conductive metal oxide). In some embodiments, the first contact structures 118 are individually formed of and include Cu. In additional embodiments, the first contact structures 118 are individually formed of and include W. In further embodiments, the first contact structures 118 of the first group 118A of the first contact structures 118 are individually formed of and include first conductive material (e.g., W); and the first contact structures 118 of the second group 118B of the first contact structures 118 are individually formed of and include a second, different conductive material (e.g., Cu).

As previously mentioned, transistors 106, the first routing structures 116, and the first contact structures 118 may form circuitries (e.g., control logic circuitries) of various first devices 120 (e.g., control logic devices) of the first circuitry region 104. In some embodiments, one or more of the first devices 120 individually comprise control logic devices including complementary metal-oxide-semiconductor (CMOS) circuitry. The first devices 120 may be configured to control various operations of other components (e.g., memory cells) of a microelectronic device (e.g., a memory device, such as a 3D NAND Flash memory device) to subsequently be formed using the first microelectronic device structure 100 and at least one additional microelectronic device structure. As a non-limiting example, the first devices 120 may include one or more (e.g., each) of charge pumps (e.g., VccP charge pumps, VNEGWL charge pumps, DVC2 charge pumps), delay-locked loop (DLL) circuitry (e.g., ring oscillators), Vdd regulators, drivers (e.g., string drivers), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitries.

Still referring to FIG. 1A, the first isolation material 122 may be formed to cover and surround portions of the transistors 106, the first routing structures 116, and the first contact structures 118. In some embodiments, the first isolation material 122 is formed to substantially cover the uppermost surfaces of the uppermost first routing structures 116 of the first microelectronic device structure 100, such that the uppermost surface of the first isolation material 122 vertically overlies the uppermost surfaces of the uppermost first routing structures 116. In additional embodiments, the first isolation material 122 is formed such that an uppermost surface thereof is substantially coplanar with uppermost surfaces of uppermost first routing structures 116 of the first microelectronic device structure 100. Accordingly, the uppermost surfaces of the first routing structures 116 are not covered by the first isolation material 122.

The first isolation material 122 may be formed of and include at least one insulative material. By way of non-limiting example, the first isolation material 122 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the first isolation material 122 is formed of and includes SiOₓ (e.g., SiO₂). The first isolation material 122 may be substantially homogeneous, or the first isolation material 122 may be heterogeneous.

Referring to next to FIG. 1B, the first microelectronic device structure 100 (FIG. 1A) may be attached (e.g., bonded) to a second microelectronic device structure 124 to form a first microelectronic device structure assembly 126. The second microelectronic device structure 124 may include a second base structure 128, and a second isolation material 130 on, over, or within the second base structure 128.

The second base structure 128 of the second microelectronic device structure 124 comprises a base material or construction upon which additional features (e.g., materials, structures, devices) of the formed. In some embodiments, the second base structure 128 comprises a wafer. The second base structure 128 may be formed of and include one or more of semiconductor material (e.g., one or more of a silicon material, such monocrystalline silicon or polycrystalline silicon (also referred to herein as “polysilicon”); silicon-germanium; germanium; gallium arsenide; a gallium nitride; gallium phosphide; indium phosphide; indium gallium nitride; and aluminum gallium nitride), a base semiconductor material on a supporting structure, glass material (e.g., one or more of borosilicate glass (BSP), phosphosilicate glass (PSG), fluorosilicate glass (FSG), borophosphosilicate glass (BPSG), aluminosilicate glass, an alkaline earth boro-aluminosilicate glass, quartz, titania silicate glass, and soda-lime glass), and ceramic material (e.g., one or more of poly-aluminum nitride (p-AlN), silicon on poly-aluminum nitride (SOPAN), aluminum nitride (AlN), aluminum oxide (e.g., sapphire; α-Al₂O₃), and silicon carbide). By way of non-limiting example, the second base structure 128 may comprise a semiconductor wafer (e.g., a silicon wafer), a glass wafer, or a ceramic wafer. The second base structure 128 may include one or more layers, structures, and/or regions formed therein and/or thereon. The second base structure 128 may be configured to facilitate safe handling of the first microelectronic device structure assembly 126 for subsequent attachment to an additional (e.g., third) microelectronic device structure, as described in further detail below.

The second isolation material 130 of the second microelectronic device structure 124 may be formed of and include at least one insulative material. A material composition of the second isolation material 130 of the second microelectronic device structure 124 may be substantially the same as a material composition of the first isolation material 122 of the first microelectronic device structure 100, or the material composition of the second isolation material 130 may be different than the material composition of the first isolation material 122. In some embodiments, the second isolation material 130 is formed of and includes a dielectric oxide material, such as SiOₓ (e.g., SiO₂). The second isolation material 130 may be substantially homogeneous, or the second isolation material 130 may be heterogeneous.

To attach the second microelectronic device structure 124 to the first microelectronic device structure 100, the second microelectronic device structure 124 may be vertically inverted (e.g., flipped upside down in the Z-direction), the second isolation material 130 thereof may be provided in physical contact with the first isolation material 122 of the first microelectronic device structure 100 at an initial interface 125 (shown by way of a dashed line in FIG. 1B), and the second isolation material 130 and the first isolation material 122 may be exposed to annealing conditions to form bonds (e.g., oxide-to-oxide bonds) between the second isolation material 130 and the first isolation material 122. By way of non-limiting example, the second isolation material 130 and the first isolation material 122 may be exposed to a temperature greater than or equal to about 400° C. (e.g., within a range of from about 400° C. to about 800° C., greater than about 800° C.) to form oxide-to-oxide bonds between the second isolation material 130 and the first isolation material 122. In some embodiments, the first isolation material 122 and the second isolation material 130 are exposed to at least one temperature greater than about 800° C. to form oxide-to-oxide bonds between the first isolation material 122 and the second isolation material 130. Following the bonding process, the resulting first microelectronic device structure assembly 126 may be vertically inverted (e.g., flipped upside down in the Z-direction) such that the first base structure 102 vertically overlies the second base structure 128, as shown in FIG. 1B. In additional embodiments, the first microelectronic device structure 100 may be vertically inverted (e.g., flipped upside down in the Z-direction) and the first isolation material 122 thereof may be provided in physical contact with the second isolation material 130 of the second microelectronic device structure 124, and the first isolation material 122 and the second isolation material 130 may be exposed to annealing conditions to form bonds (e.g., oxide-to-oxide bonds) between the first isolation material 122 and the second isolation material 130. In such embodiments, the first microelectronic device structure assembly 126 does not require vertical inversion, following the aforementioned bonding process, to position for the first base structure 102 to vertically over the second base structure 128.

Bonding the second isolation material 130 to the first isolation material 122 may form a first connected isolation structure 132. While the first isolation material 122 and the second isolation material 130 of the first connected isolation structure 132 are distinguished from one another by way of the dashed line representing the initial interface 125 before the bonding process (e.g., oxide-oxide bonding process) in FIG. 1B, the first isolation material 122 and the second isolation material 130 may be integral and continuous with one another following the bonding process. Put another way, the first connected isolation structure 132 may be a substantially monolithic (e.g., unitary) structure including the first isolation material 122 as a first region (e.g., first vertical region) thereof, and the second isolation material 130 as a second region (e.g., second vertical region) thereof. For the first connected isolation structure 132, the first isolation material 122 thereof may be attached to the second isolation material 130 thereof without a bond line.

Referring next to FIG. 1C, the first microelectronic device structure assembly 126 (FIG. 1B) may be further processed to form a modified first microelectronic device structure assembly 127. For example, as described in further detail below, a portion of the first base structure 102 may be removed; a second circuitry region 146 including additional circuitries and devices may be formed in, on, and/or over a remaining (e.g., unremoved) portion of the first base structure 102; and one or more second contact structures 136 (e.g., interconnect structures) may be formed to vertically extend completely through the remaining portion of the first base structure 102. The modified first microelectronic device structure assembly 127 is also formed to include additional features (e.g., structures, materials, regions, devices), as also described in further detail below.

A portion (e.g., backside portion, upper portion) of the first base structure 102 may be removed through one or more of a detachment process (e.g., a conventional detachment process) and a grinding process (e.g., a conventional grinding process). The material removal process may thin (e.g., reduce a vertical thickness of) the first base structure 102. The material of the first base structure 102 may then be further acted upon, as described in detail below.

As shown in FIG. 1C, the second circuitry region 146 may be positioned at a backside of the remaining portion of the first base structure 102. The second circuitry region 146 may thus be considered a backside circuitry region relative to first base structure 102. The remaining portion of the first base structure 102 may be vertically interposed between the second circuitry region 146 (e.g., backside circuitry region) and the first circuitry region 104 (e.g., front side circuitry region) of the modified first microelectronic device structure assembly 127. The second circuitry region 146 may include second devices 144 formed of and including additional circuitries. The second devices 144 may be configured to control or assist with various operations of other components of a microelectronic device (e.g., a memory device, such as a 3D NAND Flash memory device) to subsequently be formed using the modified first microelectronic device structure assembly 127 and at least one additional microelectronic device structure.

In some embodiments, the second devices 144 of the second circuitry region 146 include one or more capacitors 129 formed in, on, or over the remaining portion of the first base structure 102. An individual capacitor 129 may include an insulative material 133 interposed between a first material 131 (e.g., a semiconductor material, a metallic material) and a second material 134. The first material 131 may be formed in or on the remaining portion of the first base structure 102 (e.g., at or proximate the backside surface of the remaining portion of the first base structure 102), the insulative material 133 may be formed on the first material 131, and the second material 134 may be formed on the insulative material 133. In some embodiments, one or more of the capacitors 129 are metal-insulator-semiconductor (MIS) capacitors, wherein the first material 131 is formed of and includes semiconductor material (e.g., silicon) and the second material 134 is formed of and includes metallic material (e.g., metal, such as W). In some such embodiments, the insulative material 133 of one or more of the MIS capacitors is formed of and includes dielectric oxide (e.g., SiOₓ, such as SiO₂), such that the one or more of the MIS capacitors are metal-oxide-semiconductor (MOS) capacitors. In further embodiments, one or more of the capacitors 129 are metal-insulator-metal (MIM) capacitors, wherein the first material 131 is formed of and includes a metallic material (e.g., a first metal, such as W) and the second material 134 is formed of and includes additional metallic material (e.g., additional metal, such as W).

In further embodiments, the second devices 144 of the second circuitry region 146 include additional devices (e.g., other than or in addition to the capacitors 129) formed at least partially within the remaining portion of the first base structure 102. For example, one or more additional transistors, similar to the transistors 106 may be formed at or proximate the backside surface of the remaining portion of the first base structure 102. For an individual additional transistor, conductively doped regions (e.g., similar to the conductively doped regions 108) and a channel region (e.g., similar to the channel region 110) thereof may be formed within the remaining portion of the first base structure 102, at or proximate the backside surface (e.g., upper surface) thereof; and a gate structure (e.g., similar to the gate structure 112) and gate dielectric material (e.g., similar to the gate dielectric material 114) may be formed over the backside surface thereof. Accordingly, the remaining portion of the first base structure 102 may include the transistors 106 at or proximate a front side surface (e.g., lower surface) thereof and additional transistors at or proximate the opposing, backside surface thereof.

With continued reference to FIG. 1C, one or more second contact structures 136 may be formed to vertically extend completely through the remaining portion of the first base structure 102. The second contact structures 136 may at least partially fill vias (e.g., through silicon vias (TSVs)) formed to vertically extend through the remaining portion of the remaining portion of the first base structure 102. The second contact structures 136 may be formed to vertically extend to and contact the first routing structures 116 vertically underlying the remaining portion of the first base structure 102.

The second contact structures 136 may be formed of and include conductive material. The second contact structures 136 may facilitate electrical connections between features (e.g., structures, materials, circuitries, devices) vertically overlying the remaining portion of the first base structure 102 (e.g., over the backside surface of the remaining portion of the first base structure 102) and additional features (e.g., additional structures, additional materials, additional circuitries, additional devices) vertically underlying the remaining portion of the first base structure 102 (e.g., under the front side surface of the remaining portion of the first base structure 102). In some embodiments, the second contact structures 136 each individually comprise metallic material, such as one or more of at least one metal, at least one alloy, and at least one conductive metal-containing material (e.g., a conductive metal nitride, a conductive metal silicide, a conductive metal carbide, a conductive metal oxide). In some embodiments, the second contact structures 136 are formed of and include W.

With continued reference to FIG. 1C, a first insulative liner material 138 may be formed to substantially continuously extend over and substantially cover side surfaces of one or more of the second contact structures 136. The first insulative liner material 138 may partially fill one or more vias (e.g., one or more TSVs) containing the one or more of the second contact structures 136. The first insulative liner material 138 may be horizontally interposed between the second contact structures 136 and the remaining portion of the first base structure 102. The first insulative liner material 138 may be formed of and include at least one insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the first insulative liner material 138 is formed of and includes dielectric oxide material (e.g., SiOₓ, such as SiO₂).

Still referring to FIG. 1C, second routing structures 140 may be formed to vertically overlie (e.g., in the Z-direction) the second contact structures 136 and different devices (e.g., the capacitors 129, transistors) formed in, on, or over the remaining portion of the first base structure 102. Some of the second routing structures 140 may contact (e.g., physically contact, electrically contact) the second contact structures 136. At least some of the second routing structures 140 may be employed as additional local routing structures of a microelectronic device (e.g., a memory device, such as a 3D NAND Flash memory device). The second routing structures 140 may form portions of the circuitries of at least some of the second devices 144 of the second circuitry region 146, and/or may couple different second devices 144 of the second circuitry region 146 to one another and/or the second contact structures 136. The second routing structures 140 may each individually be formed of and include conductive material. By way of non-limiting example, the second routing structures 140 may be formed of and include one or more of at least one metal, at least one alloy, and at least one conductive metal-containing material (e.g., a conductive metal nitride, a conductive metal silicide, a conductive metal carbide, a conductive metal oxide). In some embodiments, the second routing structures 140 are formed of and include Cu. In additional embodiments, the second routing structures 140 are formed of and include W.

In addition, third contact structures 142 may be formed to vertically extend from at least some of second routing structures 140 to at least some of the devices (e.g., the capacitors 129) formed in, on, or over the remaining portion of the first base structure 102. For example, as shown in FIG. 1C, an individual third contact structure 142 may be formed to be vertically interposed between and in contact (e.g., physical contact, electrical contact) with an individual capacitor 129 and an individual second routing structures 140. The second contact structures 136 and the third contact structures 142 may be formed following the formation of the capacitors 129 (and/or additional devices, such as additional transistors), and then the second routing structures 140 may be formed over and in contact with at least some of the second contact structures 136 and at least some of the third contact structures 142. The third contact structures 142 may individually be formed of and include conductive material. By way of non-limiting example, the third contact structures 142 may be formed of and include one or more of at least one metal, at least one alloy, and at least one conductive metal-containing material (e.g., a conductive metal nitride, a conductive metal silicide, a conductive metal carbide, a conductive metal oxide). In some embodiments, the third contact structures 142 are formed of and include Cu. In additional embodiments, the third contact structures 142 are formed of and include W.

Forming the first circuitry region 104 and the second circuitry region 146 at opposing sides of the first base structure 102 than one another (e.g., a front side and a backside, respectively) effectively increases the surface area of the first base structure 102 employed to form desirable circuitries and devices relative to configurations only utilizing one side (e.g., a front side or a backside) of a base structure for the formation of desirable circuitries and devices. Accordingly, forming the first circuitry region 104 and the second circuitry region 146 at opposing sides of the first base structure 102 may facilitate increased feature density relative to conventional microelectronic device configurations, and may thus facilitate relatively enhanced performance for microelectronic devices (e.g., memory devices, such as 3D NAND devices) and electronic systems that rely on high feature density.

Optionally, the modified first microelectronic device structure assembly 127 may be formed to further first bond pads 150 formed on or over the second routing structures 140. The first bond pads 150 may be formed on or over upper surfaces of the second routing structures 140. An individual first bond pad 150 may be coupled to an individual second routing structure 140. The first bond pad 150 may directly physically contact the second routing structure 140, or the first bond pad 150 may be coupled to the second routing structure 140 by way of an intervening conductive structure (e.g., an intervening contact structure). If formed, the first bond pads 150 may be employed to couple at least some of the second routing structures 140 to additional conductive structures (e.g., bond pads, conductive contact structures), as described in further detail below. If formed, at least some of first bond pads 150 of the modified first microelectronic device structure assembly 127 may be configured for subsequent attachment to (e.g., subsequent bonding with) additional (e.g., second) bond pads of an additional (e.g., third) microelectronic device structure to be subsequently attached to modified first microelectronic device structure assembly 127, as described in further detail below. In additional embodiments, the first bond pads 150 are omitted from (e.g., are not formed within) the modified first microelectronic device structure assembly 127.

The first bond pads 150, if any, may individually be formed of and include conductive material. By way of non-limiting example, the first bond pads 150 may be formed of and include one or more of at least one metal, at least one alloy, and at least one conductive metal-containing material. In some embodiments, the first bond pads 150 are formed of and include Cu.

Still referring to FIG. 1C, at least one third isolation material 148 may be formed to cover and surround of the remaining portion of the first base structure 102, as well as portions of the capacitors 129 (and/or additional devices formed on or over the remaining portion of the first base structure 102, such as additional transistors), the second contact structures 136, the first insulative liner material 138, the second routing structures 140, the third contact structures 142, the second devices 144, and the first bond pads 150 (if any). The third isolation material 148 may be formed of and include at least one insulative material. By way of non-limiting example, the third isolation material 148 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon.

In some embodiments, the third isolation material 148 is formed of and includes SiOₓ (e.g., SiO₂). The third isolation material 148 may be substantially homogeneous, or the third isolation material 148 may be heterogeneous. If the first bond pads 150 are formed, an upper surface of the third isolation material 148 may be substantially coplanar with upper surfaces of the first bond pads 150, or the upper surface of the third isolation material 148 may vertically overlie the upper surfaces of the first bond pads 150.

Referring next to FIG. 1D, a third microelectronic device structure 152 to subsequently be attached to the modified first microelectronic device structure assembly 127 (FIG. 1C) may be formed. The third microelectronic device structure 152 may be formed to include a third base structure 154, and a memory array region 156 vertically overlying the third base structure 154. The memory array region 156 includes a stack structure 166; deep contact structures 174 and cell pillar structures 178 vertically extending through the stack structure 166; a source tier 158 vertically underlying the stack structure 166; a digit line tier 182 vertically overlying the stack structure 166; insulative line structures 188 vertically overlying the digit line tier 182; and fourth contact structures 190 vertically extending through the insulative line structures 188 to the digit line tier 182. The third microelectronic device structure 152 (including the third base structure 154 and the memory array region 156 thereof) includes additional features (e.g., structures, materials, devices), as described in further detail below.

The third base structure 154 comprises a base material or construction upon which additional features (e.g., materials, structures, devices) of the third microelectronic device structure 152 are formed. The third base structure 154 may comprise a semiconductor structure (e.g., a semiconductor wafer), or a base semiconductor material on a supporting structure. For example, the third base structure 154 may comprise a conventional silicon substrate (e.g., a conventional silicon wafer), or another bulk substrate comprising a semiconductor material. In some embodiments, the third base structure 154 comprises a silicon wafer. The third base structure 154 may include one or more layers, structures, and/or regions formed therein and/or thereon.

The source tier 158 of the additional conductive line structures 186 may be vertically interposed between the third base structure 154 and the stack structure 166 vertically overlying the third base structure 154. The source tier 158 may include at least one source structure 160 (e.g., a source plate), and at least one contact pad 162. The source structure(s) 160 and the contact pad(s) 162 may horizontally neighbor one another (e.g., in the X-direction, in the Y-direction) within the source tier 158. The source structure(s) 160 may be electrically isolated from the contact pad(s) 162, and may be positioned at substantially the same vertical position (e.g., in the Z-direction) as the contact pad(s) 162. At least one insulative material may be interposed between the source structure(s) 160, the contact pad(s) 162, the third base structure 154, and the stack structure 166, as described in further detail below.

The source structure(s) 160 and the contact pad(s) 162 may each be formed of and include conductive material. A material composition of the source structure(s) 160 may be substantially the same as a material composition of the contact pad(s) 162. In some embodiments, the source structure(s) 160 and the contact pad(s) 162 are formed of and include one or more of a metal, an alloy, and a conductive metal-containing material (e.g., a conductive metal nitride, a conductive metal silicide, a conductive metal carbide, a conductive metal oxide).

As a non-limiting example, the source structure(s) 160 and the contact pad(s) 162 may be formed of and include W. In additional embodiments, the source structure(s) 160 and the contact pad(s) 162 are formed of and include conductively doped semiconductor material, such as a conductively doped form of one or more of a silicon material, such as monocrystalline silicon or polycrystalline silicon; a silicon-germanium material; a germanium material; a gallium arsenide material; a gallium nitride material; and an indium phosphide material. As a non-limiting example, the source structure(s) 160 and the contact pad(s) 162 may be formed of and include silicon (e.g., polycrystalline silicon) doped with at least one dopant (e.g., one or more of at least one N-type dopant, at least one P-type dopant, and at least another dopant).

The source structure(s) 160 of the source tier 158 may be coupled to the cell pillar structures 178. In some embodiments, the source structure(s) 160 directly physically contact the cell pillar structures 178. In additional embodiments, contact structures may vertically intervene between the source structure(s) 160 and the cell pillar structures 178. In addition, the source structure(s) 160 may also be coupled to and/or may subsequently be coupled to additional structures (e.g., contact structures, routing structures, pad structures) present within and/or to subsequently be present within (e.g., following subsequent processing acts) boundaries the third microelectronic device structure 152, as described in further detail below.

The contact pad(s) 162 of the source tier 158 may be coupled to additional conductive features (e.g., conductive contact structures, conductive pillars, conductively filled vias) within the stack structure 166. For example, as shown in FIG. 1D, the contact pad(s) 162 may be coupled to one or more of the deep contact structures 174 vertically extending through the stack structure 166. In some embodiments, the contact pad(s) 162 directly physically contact the deep contact structure(s) 174. In additional embodiments, additional contact structures may vertically intervene between the contact pad(s) 162 and the deep contact structure(s) 174, and may couple the contact pad(s) 162 to the deep contact structure(s) 174. In addition, the contact pad(s) 162 may be coupled to additional structures (e.g., interconnect structures, routing structures, pad structures) may also be coupled to and/or may subsequently be coupled to additional structures (e.g., contact structures, routing structures, pad structures) present within and/or to subsequently be present within (e.g., following subsequent processing acts) the third microelectronic device structure 152, as described in further detail below.

As shown in FIG. 1D, fifth contact structures 164 may be formed to be vertically interposed between the source tier 158 and the third base structure 154. The fifth contact structures 164 may vertically extend from the source tier 158 (e.g., from the source structure(s) 160, from the contact pad(s) 162) toward the third base structure 154. The fifth contact structures 164 may vertically terminate above, at, or within the third base structure 154. The fifth contact structures 164 may, for example, couple the source structure(s) 160 and/or the contact pad(s) 162 of the source tier 158 to features (e.g., structures, materials, regions, devices) of the third base structure 154. The fifth contact structures 164 may individually be formed of and include conductive material. By way of non-limiting example, the fifth contact structures 164 may be formed of and include one or more of at least one metal, at least one alloy, and at least one conductive metal-containing material (e.g., a conductive metal nitride, a conductive metal silicide, a conductive metal carbide, a conductive metal oxide). In some embodiments, the fifth contact structures 164 are formed of and include Cu. In additional embodiments, the fifth contact structures 164 are formed of and include W.

Still referring to FIG. 1D, the stack structure 166 may be formed to vertically overlie the source tier 158, and may include a vertically alternating (e.g., in the Z-direction) sequence of conductive material 168 and insulative material 170 arranged in tiers 172. An individual tier 172 of the stack structure 166 may include the conductive material 168 vertically neighboring the insulative material 170. The stack structure 166 may be formed to include any desired number of the tiers 172, such as greater than or equal to sixteen (16) of the tiers 172, greater than or equal to thirty-two (32) of the tiers 172, greater than or equal to sixty-four (64) of the tiers 172, greater than or equal to one hundred and twenty-eight (128) of the tiers 172, or greater than or equal to two hundred and fifty-six (256) of the tiers 172.

The conductive material 168 of the tiers 172 of the stack structure 166 may be formed of and include formed of and include one or more of at least one metal, at least one alloy, at least one conductive metal-containing material, and at least one conductively doped semiconductor material. In some embodiments, the conductive material 168 of one or more (e.g., each) of the tiers 172 of the stack structure 166 is formed of and includes W. The conductive material 168 of an individual tier 172 may substantially homogeneous, or the conductive material 168 of the tier 172 may be substantially heterogeneous.

Optionally, one or more liner materials (e.g., insulative liner material(s), conductive liner material(s)) may also be formed around the conductive material 168 of one or more (e.g., each) of the tiers 172 of the stack structure 166. The liner material(s) may, for example, be formed of and include one or more a metal (e.g., titanium, tantalum), an alloy, a metal nitride (e.g., tungsten nitride, titanium nitride, tantalum nitride), and a metal oxide (e.g., aluminum oxide). In some embodiments, the liner material(s) comprise at least one conductive material employed as a seed material for the formation of the conductive material 168. In some embodiments, the liner material(s) comprise titanium nitride (TiNₓ). In further embodiments, the liner material(s) further include aluminum oxide (AlOₓ). As a non-limiting example, AlOₓ may be formed directly adjacent the insulative material 170 of one or more (e.g., each) of the tiers 172, TiNₓ may be formed directly adjacent the AlOₓ, and W may be formed directly adjacent the TiNₓ. For clarity and ease of understanding the description, the liner material(s) are not illustrated in FIG. 1D, but it will be understood that the liner material(s) may be disposed around the conductive material 168 of one or more (e.g., each) of the tiers 172 of the stack structure 166.

The insulative material 170 of the tiers 172 of the stack structure 166 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the insulative material 170 of one or more (e.g., each) of the tiers 172 of the stack structure 166 is formed of and includes dielectric oxide material, such as SiOₓ (e.g., SiO₂). The insulative material 170 of an individual tier 172 may substantially homogeneous, or the insulative material 170 of the tier 172 may be substantially heterogeneous.

The cell pillar structures 178 may vertically extend through the tiers 172 of the stack structure 166, and may be coupled to the source structure(s) 160 of the source tier 158. The cell pillar structures 178 may individually be formed of and include a stack of materials. By way of non-limiting example, an individual cell pillar structure 178 may be formed to include a first dielectric oxide material (e.g., SiOₓ, such as SiO₂; AlOₓ, such as Al₂O₃), a dielectric nitride material (e.g., SiN_{y}, such as Si₃N₄), a second oxide dielectric material (e.g., SiOₓ, such as SiO₂), a semiconductor material (e.g., Si, such as polycrystalline Si), and a dielectric fill material (e.g., a dielectric oxide, a dielectric nitride, air). The first dielectric oxide material may be formed on or over surfaces of the conductive material 168 and the insulative material 170 of the tiers 172 of stack structure 166 at least partially defining horizontal boundaries of the cell pillar structures 178; the dielectric nitride material may be horizontally surrounded by the first dielectric oxide material; the second oxide dielectric material may be horizontally surrounded by the dielectric nitride material; the semiconductor material may be horizontally surrounded by the second oxide dielectric material; and the dielectric fill material may be horizontally surrounded by the semiconductor material.

With continued reference to FIG. 1A, intersections of the cell pillar structures 178 and the conductive material 168 of the tiers 172 of the stack structure 166 may define vertically extending strings of memory cells 180 coupled in series with one another within the stack structure 166. In some embodiments, the memory cells 180 formed at the intersections of the conductive material 168 and the cell pillar structures 178 within different tiers 172 of the stack structure 166 comprise so-called “MONOS” (metal—oxide—nitride—oxide-semiconductor) memory cells. In additional embodiments, the memory cells 180 comprise so-called “TANOS” (tantalum nitride—aluminum oxide—nitride—oxide—semiconductor) memory cells, or so-called “BETANOS” (band/barrier engineered TANOS) memory cells, each of which are subsets of MONOS memory cells. In further embodiments, the memory cells 180 comprise so-called “floating gate” memory cells including floating gates (e.g., metallic floating gates) as charge storage structures. The floating gates may horizontally intervene between central structures of the cell pillar structures 178 and the conductive material 168 of the different tiers 172 of the stack structure 166.

As shown in FIG. 1D, the deep contact structures 174 may also vertically extend through the tiers 172 of the stack structure 166. The deep contact structures 174 may be configured and positioned to electrically connect one or more features (e.g., structures, material, devices) of the third microelectronic device structure 152 vertically overlying the stack structure 166 with one or more additional features of the third microelectronic device structure 152 vertically underlying the stack structure 166. One or more of the deep contact structures 174 may be coupled to the source structure(s) 160 of the source tier 158; and one or more other of the deep contact structures 174 may be coupled to the contact pad(s) 162 of the source tier 158. The deep contact structures 174 may be formed of and include conductive material. In some embodiments, the deep contact structures 174 are individually formed of and include W. In additional embodiments, the deep contact structures 174 are individually formed of and include conductively doped polycrystalline silicon.

Insulative liner structures 176 may be formed to substantially continuously extend over and substantially cover side surfaces of the deep contact structures 174. The insulative liner structures 176 may be horizontally interposed between the deep contact structures 174 and the conductive material 168 (and the insulative material 170) of the tiers 172 of the stack structure 166. The insulative liner structures 176 may be formed over and include at least one insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, each of the insulative liner structures 176 is formed of and includes dielectric oxide material (e.g., SiOₓ, such as SiO₂).

With continued reference to FIG. 1D, the digit line tier 182 may be vertically interposed between the stack structure 166 and the insulative line structures 188 vertically overlying the stack structure 166. The digit line tier 182 may include digit line structures 184 (e.g., digit lines, bit lines, data lines), and one or more additional conductive line structures 186. The digit line structures 184 and the additional conductive line structure(s) 186 may horizontally neighbor one another (e.g., in the X-direction, in the Y-direction) within the digit line tier 182. The digit line structures 184 may be electrically isolated from the additional conductive line structure(s) 186, and may be positioned at substantially the same vertical position (e.g., in the Z-direction) as the additional conductive line structure(s) 186. At least one insulative material may be interposed between the digit line structures 184 and the additional conductive line structure(s) 186, as described in further detail below.

The digit line structures 184 and the additional conductive line structure(s) 186 may individually be formed of and include conductive material. A material composition of the digit line structures 184 may be substantially the same as a material composition of the additional conductive line structure(s) 186. In some embodiments, the digit line structures 184 and the additional conductive line structure(s) 186 are formed of and include one or more of a metal, an alloy, and a conductive metal-containing material (e.g., a conductive metal nitride, a conductive metal silicide, a conductive metal carbide, a conductive metal oxide). As a non-limiting example, the digit line structures 184 and the additional conductive line structure(s) 186 may be formed of and include W. In additional embodiments, the digit line structures 184 and the additional conductive line structure(s) 186 are formed of and include conductively doped semiconductor material. As a non-limiting example, the digit line structures 184 and the additional conductive line structure(s) 186 may be formed of and include silicon (e.g., polycrystalline silicon) doped with at least one dopant (e.g., one or more of at least one N-type dopant, at least one N-type dopant, and at least another dopant).

The digit line structures 184 may be formed vertically over and in electrical communication with the cell pillar structures 178 (and, hence, the vertically extending strings of memory cells 180). The digit line structures 184 may exhibit horizontally elongate shapes extending in parallel in a first horizontal direction (e.g., the Y-direction). As used herein, the term “parallel” means substantially parallel. The digit line structures 184 may each exhibit substantially the same dimensions (e.g., width in the X-direction, length in a Y-direction, height in the Z-direction), shape, and spacing (e.g., in the X-direction). In additional embodiments, one or more of the digit line structures 184 may exhibit one or more of at least one different dimension (e.g., a different length, a different width, a different height) and a different shape than one or more other of the digit line structures 184, and/or the spacing (e.g., in the X-direction) between at least two horizontally neighboring digit line structures 184 may be different than the spacing between at least two other horizontally neighboring digit line structures 184.

The additional conductive line structure(s) 186 of the digit line tier 182 may be coupled to additional conductive features (e.g., conductive contact structures, conductive pillars, conductively-filled vias) within the stack structure 166. For example, as shown in FIG. 1D, the additional conductive line structure(s) 186 may be coupled to one or more of the deep contact structures 174 vertically extending through the stack structure 166. In some embodiments, the additional conductive line structure(s) 186 directly physically contact the deep contact structure(s) 174. In additional embodiments, additional contact structures may vertically intervene between the additional conductive line structure(s) 186 and the deep contact structure(s) 174, and may electrically couple the additional conductive line structure(s) 186 to the deep contact structure(s) 174.

The insulative line structures 188 may be formed on or over the digit line structures 184 and the additional conductive line structure(s) 186 of the digit line tier 182. The insulative line structures 188 may serve as insulative cap structures (e.g., dielectric cap structures) for the digit line structures 184 and the additional conductive line structure(s) 186. The insulative line structures 188 may have horizontally elongate shapes extending in parallel in the first horizontal direction (e.g., the Y-direction). Horizontal dimensions, horizontal pathing, and horizontal spacing of the insulative line structures 188 may be substantially the same as the horizontal dimensions, horizontal pathing, and horizontal spacing of the digit line structures 184 and the additional conductive line structure(s) 186.

The insulative line structures 188 may be formed of and include insulative material. By way of non-limiting example, the insulative line structures 188 may each individually be formed of and include a dielectric nitride material, such as SiN_{y} (e.g., Si₃N₄). The insulative line structures 188 may individually be substantially homogeneous, or may individually be heterogeneous.

The fourth contact structures 190 may be formed to vertically extend through the insulative line structures 188, and may contact the digit line structures 184 and the additional conductive line structure(s) 186 of the digit line tier 182. For an individual fourth contact structure 190, a first portion thereof may vertically overlie one of the insulative line structures 188, and a second portion thereof may vertically extend through the insulative line structure 188 and contact (e.g., physically contact, electrically contact) one of the digit line structures 184 or one of the additional conductive line structure(s) 186. An individual fourth contact structure 190 may be at least partially (e.g., substantially) horizontally aligned in the X-direction with an individual insulative line structure 188. For example, horizontal centerlines of the fourth contact structures 190 in the X-direction may be substantially aligned with horizontal centerlines of the insulative line structures 188 in the X-direction. In addition, the fourth contact structures 190 may be formed at desired locations in the Y-direction along the insulative line structures 188. In some embodiments, at least some of the fourth contact structures 190 are provided at different positions in the Y-direction than one another. For example, a first of the fourth contact structures 190 may be provided at different position along a length in the Y-direction of a first of the insulative line structures 188 as compared to a position of a second of the fourth contact structures 190 along a length in the Y-direction of a second of the insulative line structures 188. At least some (e.g., all) of the fourth contact structures 190 may be horizontally offset from one another in the Y-direction. In additional embodiments, two or more of the fourth contact structures 190 are horizontally aligned with one another in the Y-direction.

The fourth contact structures 190 may individually be formed of and include conductive material. By way of non-limiting example, the fourth contact structures 190 may individually be formed of and include one or more of at least one metal, at least one alloy, and at least one conductive metal-containing material (e.g., a conductive metal nitride, a conductive metal silicide, a conductive metal carbide, a conductive metal oxide). In some embodiments, the fourth contact structures 190 are formed of and include Cu. In additional embodiments, the fourth contact structures 190 are formed of and include W.

Still referring to FIG. 1D, the third microelectronic device structure 152 may further include second bond pads 194 formed on or over the fourth contact structures 190. The second bond pads 194 may be formed on or over upper surfaces of the fourth contact structures 190. One or more of the second bond pads 194 may individually be formed to horizontally extend over multiple insulative line structures 188. An individual second bond pad 194 may be coupled to an individual fourth contact structure 190. The second bond pads 194 may be employed to couple at least some of the fourth contact structures 190 to additional conductive structures (e.g., bond pads, conductive contact structures), as described in further detail below. In embodiments wherein the modified first microelectronic device structure assembly 127 (FIG. 1C) is formed to include the first bond pads 150 (FIG. 1C), at least some of the second bond pads 194 of the third microelectronic device structure 152 may be configured for subsequent attachment to (e.g., subsequent bonding with) at least some of the first bond pads 150 (FIG. 1C) of the modified first microelectronic device structure assembly 127 (FIG. 1C), as described in further detail below.

The second bond pads 194 may individually be formed of and include conductive material. By way of non-limiting example, the second bond pads 194 may be formed of and include one or more of at least one metal, at least one alloy, and at least one conductive metal-containing material. A material composition of the second bond pads 194 may be substantially the same as a material composition of the fourth contact structures 190, or the material composition of the second bond pads 194 may be different than the material composition of the fourth contact structures 190. In some embodiments, the second bond pads 194 are formed of and include Cu.

Still referring to FIG. 1D, at least one fourth isolation material 192 may be formed to cover and surround of portions of the third base structure 154, the source structure(s) 160, the contact pad(s) 162, the stack structure 166 (including the conductive material 168 and the insulative material 170 of the tiers 172 thereof), the digit line structures 184, the additional conductive line structure(s) 186, the insulative line structures 188, the fourth contact structures 190, and the second bond pads 194. The fourth isolation material 192 may be formed of and include at least one insulative material. By way of non-limiting example, the fourth isolation material 192 may be formed of and include one or more of at least one dielectric oxide material, at least one dielectric nitride material, at least one dielectric oxynitride material, at least one dielectric carboxynitride material, and amorphous carbon. In some embodiments, the fourth isolation material 192 is formed of and includes SiOₓ (e.g., SiO₂). The fourth isolation material 192 may be substantially homogeneous, or the fourth isolation material 192 may be heterogeneous. An upper surface of the fourth isolation material 192 may be substantially coplanar with upper surfaces of the second bond pads 194, or the upper surface of the fourth isolation material 192 may vertically overlie the upper surfaces of the second bond pads 194.

Referring to next to FIG. 1E, following the formation of the modified first microelectronic device structure assembly 127 and the separate formation of the third microelectronic device structure 152, the modified first microelectronic device structure assembly 127 may be vertically inverted (e.g., flipped upside down in the Z-direction) provided in physical contact with the third microelectronic device structure 152 at an initial interface 195 (shown by way of a dashed line in FIG. 1E). Thereafter, the modified first microelectronic device structure assembly 127 may be attached (e.g., bonded) to the third microelectronic device structure 152 to form a second microelectronic device structure assembly 196. Alternatively, the third microelectronic device structure 152 may be vertically inverted (e.g., flipped upside down in the Z-direction), brought into physical contact with, and attached to the modified first microelectronic device structure assembly 127 to form the second microelectronic device structure assembly 196; and thereafter the second microelectronic device structure assembly 196 may be vertically inverted (e.g., flipped upside down in the Z-direction) such that the second base structure 128 vertically overlies the third base structure 154. In FIG. 1E, vertical boundaries of the modified first microelectronic device structure assembly 127 relative to the third microelectronic device structure 152 prior to the attachment of the modified first microelectronic device structure assembly 127 to the third microelectronic device structure 152 to form the second microelectronic device structure assembly 196 are depicted by way of the dashed line representing the initial interface 195 before the attachment process.

Attaching the modified first microelectronic device structure assembly 127 to the third microelectronic device structure 152 may include bonding (e.g., oxide-oxide bonding) the third isolation material 148 of the modified first microelectronic device structure assembly 127 to the fourth isolation material 192 of the third microelectronic device structure 152. By way of non-limiting example, the third isolation material 148 and the fourth isolation material 192 may be exposed to an annealing temperature greater than or equal to about 400° C. (e.g., within a range of from about 400° C. to about 800° C., greater than about 800° C.) to form oxide-to-oxide bonds between the third isolation material 148 and the fourth isolation material 192. In some embodiments, the third isolation material 148 and the fourth isolation material 192 are exposed to at least one temperature greater than about 800° C. to form oxide-to-oxide bonds between the third isolation material 148 and the fourth isolation material 192. As shown in FIG. 1E, bonding the third isolation material 148 and the fourth isolation material 192 may form a second connected isolation structure 198. While the third isolation material 148 and the fourth isolation material 192 of the second connected isolation structure 198 are distinguished from one another by way of the dashed line representing the initial interface 195 before the bonding process in FIG. 1E, the third isolation material 148 and the fourth isolation material 192 may be integral and continuous with one another following the bonding process. Put another way, the second connected isolation structure 198 may be a substantially monolithic (e.g., unitary) structure including the third isolation material 148 as a first region (e.g., first vertical region) thereof, and the fourth isolation material 192 as a second region (e.g., second vertical region) thereof. For the second connected isolation structure 198, the third isolation material 148 thereof may be attached to the fourth isolation material 192 thereof without a bond line.

In embodiments wherein the modified first microelectronic device structure assembly 127 is formed to include the first bond pads 150, attaching the modified first microelectronic device structure assembly 127 to the third microelectronic device structure 152 may further include bonding (e.g., metal-to-metal bonding) at least some of the first bond pads 150 of the modified first microelectronic device structure assembly 127 to at least some of the second bond pads 194 of the third microelectronic device structure 152. By way of non-limiting example, the first bond pads 150 and the second bond pads 194 may be exposed to an annealing temperature greater than or equal to about 400° C. (e.g., within a range of from about 400° C. to about 800° C., greater than about 800° C.) to form metal-to-metal bonds between at least some of the first bond pads 150 and at least some of the second bond pads 194. In some embodiments, the first bond pads 150 and the second bond pads 194 are exposed to at least one temperature greater than about 800° C. to form metal-to-metal bonds between the first bond pads 150 and the second bond pads 194. As shown in FIG. 1E, bonding an individual first bond pad 150 to an individual second bond pad 194 may form an individual connected pad structure 200. While the first bond pads 150 and the second bond pads 194 of the connected pad structures 200 are distinguished from one another by way of the dashed line representing the initial interface 195 before the bonding process in FIG. 1E, the first bond pads 150 and the second bond pads 194 of the connected pad structures 200 may be integral and continuous with one another following the bonding process. Put another way, an individual connected pad structure 200 may be a substantially monolithic (e.g., unitary) structure including an individual first bond pad 150 as a first region (e.g., first vertical region) thereof, and an individual second bond pad 194 as a second region (e.g., second vertical region) thereof. For an individual connected pad structure 200, the first bond pad 150 thereof may be attached to the second bond pad 194 thereof without a bond line.

Bonding the first bond pads 150 (if any) of the modified first microelectronic device structure assembly 127 to the second bond pads 194 of the third microelectronic device structure 152 may be performed in addition to bonding the third isolation material 148 of the modified first microelectronic device structure assembly 127 to the fourth isolation material 192 of the third microelectronic device structure 152. Thus, if the modified first microelectronic device structure assembly 127 is formed to include the first bond pads 150, the modified first microelectronic device structure assembly 127 may be attached to the third microelectronic device structure 152 through a combination of oxide-to-oxide bonding (e.g., between the third isolation material 148 to the fourth isolation material 192) and metal-to-metal bonding (e.g., between the first bond pads 150 and the second bond pads 194). Bonding the first bond pads 150 to the second bond pads 194 may result from the same annealing process employed to bond the third isolation material 148 to the fourth isolation material 192.

Referring next to FIG. 1F, after forming the second microelectronic device structure assembly 196 (FIG. 1E), the second base structure 128 (FIG. 1E) may be removed. Thereafter, an interconnect region 224 including back-end-of-line (BEOL) structures may be formed vertically over the first circuitry region 104. In addition, optionally, prior to the formation of at least some of the BEOL structures, one or more pass-through contact structure(s) 202 may be formed to vertically extend completely through the first circuitry region 104 and the second circuitry region 146 and into the memory array region 156.

The second base structure 128 (FIG. 1E) may be removed through one or more of a detachment processes and a grinding process. As shown in FIG. 1F, in some embodiments, at least a portion of first connected isolation structure 132 remains over uppermost surfaces of the first routing structures 116 following the material removal process. In additional embodiments, the material removal process substantially removes portions of the first connected isolation structure 132 vertically overlying uppermost surfaces of the first routing structures 116 to expose some of the first routing structures 116.

If formed, the pass-through contact structure(s) 202 may individually vertically extend through the first routing structures 116, the first connected isolation structure 132, the remainder of the first base structure 102, and the second connected isolation structure 198. The pass-through contact structure(s) 202 may vertically extend into or into the tiers 172 of the stack structure 166. As shown in FIG. 1E, in some embodiments, the pass-through contact structure(s) 202 vertically extend to and contact some of the deep contact structures 174 vertically extending through the tiers 172 of the stack structure 166. The pass-through contact structure(s) 202 may be configured and positioned to electrically connect one or more features (e.g., structures, material, devices) formed to vertically overlie the first routing structures 116 with one or more the deep contact structures 174 (and, hence, additional features of the third microelectronic device structure 152 vertically underlying the stack structure 166, such as the source structure(s) 160). The pass-through contact structure(s) 202 may be formed of and include conductive material. In some embodiments, the pass-through contact structure(s) 202 are individually formed of and include W. In additional embodiments, the pass-through contact structure(s) 202 are individually formed of and include conductively doped polycrystalline silicon.

Additional insulative liner structures 204 may be formed to substantially continuously extend over and substantially cover side surfaces of the pass-through contact structure(s) 202 (in any). The additional insulative liner structures 204 may be horizontally interposed between the pass-through contact structure(s) 202 and additional features (e.g., structures, materials, devices) within the first circuitry region 104, the second circuitry region 146, and the memory array region 156. The additional insulative liner structures 204 may be formed over and include at least one insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, each of the additional insulative liner structures 204 is formed of and includes dielectric oxide material (e.g., SiOₓ, such as SiO₂).

Still referring to FIG. 1F, the BEOL structures formed vertically over the first circuitry region 104 may include third routing structures 206, conductive pad structures 208, sixth contact structures 210, seventh contact structures 212, and eighth contact structures 216. The third routing structures 206 may vertically overlie the first routing structures 116. The conductive pad structures 208 may vertically overlie the third routing structures 206. The sixth contact structures 210 vertically extend between and couple some of the third routing structures 206 to some of the features (e.g., some of the first routing structures 116, the pass-through contact structure(s) 202 (if any)) at least partially positioned within the first circuitry region 104. The seventh contact structures 212 may vertically extend between and couple the some of the third routing structures 206 to others of the third routing structures 206. The eighth contact structures 216 may vertically extend between and couple some of the third routing structures 206 to the conductive pad structures 208. In additional embodiments, one or more of the conductive pad structures 208 are formed to directly physically contact one or more of the third routing structures 206.

The third routing structures 206, the conductive pad structures 208, the sixth contact structures 210, the seventh contact structures 212, and the eighth contact structures 216 may individually be formed of and include conductive material. By way of non-limiting example, the third routing structures 206, the conductive pad structures 208, the sixth contact structures 210, the seventh contact structures 212, and the eighth contact structures 216 may individually be formed of and include one or more of at least one metal, at least one alloy, and at least one conductive metal-containing material (e.g., a conductive metal nitride, a conductive metal silicide, a conductive metal carbide, a conductive metal oxide). In some embodiments, the third routing structures 206 are individually formed of and include Cu; the conductive pad structures 208 are individually formed of and include Al; and the sixth contact structures 210, the seventh contact structures 212, and the eighth contact structures 216 are individually formed of and include W.

Still referring to FIG. 1F, at least one fifth isolation material 218 may be formed to cover and surround the third routing structures 206, the conductive pad structures 208, the seventh contact structures 212, and the eighth contact structures 216. In some embodiments, the fifth isolation material 218 is formed of and includes at least one dielectric oxide material, such as SiOₓ (e.g., SiO₂). In additional embodiments, the fifth isolation material 218 is formed of and includes at least one low-k dielectric material, such as one or more of SiOₓC_{y}, SiOₓN_{y}, SiCₓO_{y}H_{z}, and SiOₓC_{z}N_{y}. The fifth isolation material 218 may be substantially homogeneous, or the fifth isolation material 218 may be heterogeneous. In addition, one or more openings 220 may be formed within the fifth isolation material 218 to expose one or more of the conductive pad structures 208. The openings 220 may, for example, facilitate access to the conductive pad structures 208 by one or more additional structures (e.g., wires, such as bond wires) of a relatively larger device.

The interconnect region 224 may include the third routing structures 206, the conductive pad structures 208, the sixth contact structures 210, the seventh contact structures 212, the eighth contact structures 216, and the fifth isolation material 218. In addition, the formation of the interconnect region 224 may effectuate the formation of a microelectronic device 226 (e.g., a memory device, such as a 3D NAND Flash memory device). The microelectronic device 226 may include, without limitation, the interconnect region 224, the first circuitry region 104 vertically under the interconnect region 224, the second circuitry region 146 vertically under the first circuitry region 104, and the memory array region 156 vertically under the second circuitry region 146. At least the third routing structures 206 and the conductive pad structures 208 of the interconnect region 224 may serve as global routing structures for the microelectronic device 226. The third routing structures 206 and the conductive pad structures 208 may, for example, be configured to receive global signals from an external bus, and to relay the global signals to other components (e.g., structures, devices) of the microelectronic device 226.

The processing stages and structural configurations described above with reference to FIGS. 1A through 1F resolve limitations on conventional microelectronic device configurations and associated conventional microelectronic device performance (e.g., speed, data transfer rates, power consumption) that may otherwise result from thermal budget constraints imposed by conventional formation and/or conventional processing of arrays (e.g., memory cell arrays, memory element arrays, access device arrays) for a conventional microelectronic device. For example, by forming the modified first microelectronic device structure assembly 127 (FIG. 1C) separate from the third microelectronic device structure 152 (FIG. 1D) and then attaching (e.g., bonding) the modified first microelectronic device structure assembly 127 (FIG. 1C) to the third microelectronic device structure 152 (FIG. 1D) permits circuitries and devices within at least the first circuitry region 104 and the second circuitry region 146 of the modified first microelectronic device structure assembly 127 (FIG. 1C) to be unimpaired by processing conditions (e.g., temperatures, pressures, materials) required to form circuitries and devices (e.g., memory cells) of at least the memory array region 156 of the third microelectronic device structure 152 (FIG. 1D).

Thus, in accordance with embodiments of the disclosure, a method of forming a microelectronic device includes forming a first assembly including a semiconductor base structure, a first circuitry region including first devices at a first boundary of the semiconductor base structure, and a second circuitry region including second devices at a second boundary of the semiconductor base structure vertically offset from the first boundary. A microelectronic device structure is formed and includes a stack structure including tiers individually including conductive material and insulative material vertically adjacent the conductive material, and cell pillar structures including semiconductor material vertically extending through the stack structure. The first assembly is attached to the microelectronic device structure to form a second assembly.

Furthermore, in accordance with embodiments of the disclosure, a microelectronic device includes a stack structure, cell pillar structures, a semiconductor structure, first devices, second devices, and conductive contact structures. The stack structure includes tiers each including conductive material and insulative material vertically neighboring the conductive material. The cell pillar structures include semiconductor materiel vertically extending through the stack structure. The semiconductor structure vertically overlies the stack structure. The first devices are at a lower boundary of the semiconductor structure. The second devices are at an upper boundary of the semiconductor structure. The conductive contact structures vertically extending from a vertical position of at least some of the second devices, completely through the semiconductor structure, and at least to an additional vertical position of at least some of the first devices.

Moreover, in accordance with embodiments of the disclosure, a memory device includes a stack structure, strings of memory cells, a source structure, digit lines, a semiconductor structure, capacitors, control logic devices, and conductive contact structures. The stack structure includes tiers each including conductive material and insulative material vertically neighboring the conductive material. The strings of memory cells vertically extend through the stack structure. The source structure vertically underlies the stack structure and is coupled to the strings of memory cells. The digit lines vertically overlie the stack structure and are coupled to the strings of memory cells. The semiconductor structure vertically overlies the digit lines. The capacitors partially vertically overlap lowermost boundaries of the semiconductor structure. The control logic devices partially vertically overlap uppermost boundaries of semiconductor structure and are coupled to the strings of memory cells. The conductive contact structures vertically extend through the semiconductor structure and couple at least some the capacitors to some of the control logic devices.

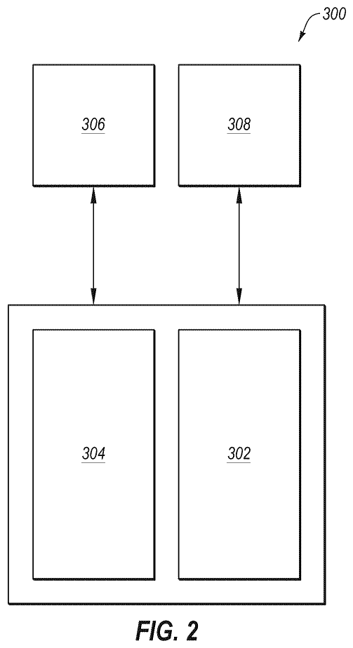

Microelectronic devices (e.g., the microelectronic device 226 (FIG. 1F)) in accordance with embodiments of the disclosure may be used in embodiments of electronic systems of the disclosure. For example, FIG. 2 is a schematic block diagram of an illustrative electronic system 300 according to embodiments of disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 300 includes at least one memory device 302. The memory device 302 may include, for example, a microelectronic device (e.g., the microelectronic device 226 (FIG. 1F)) previously described herein. The electronic system 300 may further include at least one electronic signal processor device 304 (often referred to as a “microprocessor”). The electronic signal processor device 304 may, optionally, comprise a microelectronic device (e.g., the microelectronic device 226 (FIG. 1F)) previously described herein. While the memory device 302 and the electronic signal processor device 304 are depicted as two (2) separate devices in FIG. 2, in additional embodiments, a single (e.g., only one) memory/processor device having the functionalities of the memory device 302 and the electronic signal processor device 304 is included in the electronic system 300. In such embodiments, the memory/processor device may include a microelectronic device (e.g., the microelectronic device 226 (FIG. 1F)) previously described herein. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, and/or a speaker. In some embodiments, the input device 306 and the output device 308 comprise a single touchscreen device that can be used both to input information to the electronic system 300 and to output visual information to a user. The input device 306 and the output device 308 may communicate electrically with one or more of the memory device 302 and the electronic signal processor device 304.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A method of forming a microelectronic device, comprising:
forming a first assembly comprising:
a semiconductor base structure;
a first circuitry region comprising first devices at a first boundary of the semiconductor base structure; and
a second circuitry region comprising second devices at a second boundary of the semiconductor base structure vertically offset from the first boundary;
forming a microelectronic device structure comprising:
a stack structure comprising tiers individually comprising conductive material and insulative material vertically adjacent the conductive material; and
cell pillar structures comprising semiconductor material vertically extending through the stack structure; and
attaching the first assembly to the microelectronic device structure to form a second assembly.

2. The method of claim 1, wherein forming the first assembly comprises:
forming an additional microelectronic device structure comprising an initial semiconductor base structure comprising and the first devices of the first circuitry region;
forming a further microelectronic device structure comprising an additional base structure;
bonding the additional microelectronic device structure to the further microelectronic device structure;
removing a portion of the initial semiconductor base structure after attaching the additional microelectronic device structure to the further microelectronic device structure to form the semiconductor base structure; and
forming the second devices of the second circuitry region after forming the semiconductor base structure.

3. The method of claim 1, wherein forming the first assembly comprises:
forming the first devices of the first circuitry region to comprise control logic devices including transistors vertically overlapping and partially defined by the semiconductor base structure; and
forming the second devices of the second circuitry region to comprise capacitors.

4. The method of claim 3, further comprising forming the capacitors to comprise one or more of metal-insulator-semiconductor (MIS) capacitors and metal-insulator-metal (MIM) capacitors.

5. The method of claim 1, further comprising forming the first assembly to further comprise conductive contact structures vertically extending from the first circuitry region, completely through the semiconductor base structure, and to the second circuitry region.

6. The method of claim 1, wherein attaching the first assembly to the microelectronic device structure comprising bonding dielectric oxide material of the first assembly to additional dielectric oxide material of the microelectronic device structure.

7. The method of claim 6, wherein attaching the first assembly to the microelectronic device structure further comprises bonding conductive bond pads of the first assembly embedded within the dielectric oxide material to additional conductive bond pads of the microelectronic device structure embedded within the additional dielectric oxide material.

8. The method of claim 1, further comprising forming the microelectronic device structure to further comprise:
digit line structures vertically overlying the stack structure and coupled to the cell pillar structures;
a source structure vertically underlying the stack structure and coupled to the cell pillar structures; and
conductive contact structures horizontally offset from the cell pillar structures and individually vertically extending through the stack structure and to a vertical position of the source structure.

9. The method of claim 1, further comprising, after forming the second assembly, forming conductive contact structures vertically extending through the second circuitry region, the semiconductor base structure, and the first circuitry region of the first assembly and at least to the stack structure of the microelectronic device structure.

10. The method of claim 1, further comprising forming an interconnect region over the second assembly, the interconnect region comprising:
conductive routing structures vertically overlying and coupled to at least some of the first devices; and
conductive pad structures vertically overlying and coupled to at least some of the conductive routing structures.

11. A microelectronic device, comprising:
a stack structure comprising tiers each comprising conductive material and insulative material vertically neighboring the conductive material;
cell pillar structures comprising semiconductor materiel vertically extending through the stack structure;
a semiconductor structure vertically overlying the stack structure;
first devices at a lower boundary of the semiconductor structure;
second devices at an upper boundary of the semiconductor structure; and
conductive contact structures vertically extending from a vertical position of at least some of the second devices, completely through the semiconductor structure, and at least to an additional vertical position of at least some of the first devices.

12. The microelectronic device of claim 11, wherein the first devices comprise one or more of metal-insulator-semiconductor (MIS) capacitors and metal-insulator-metal (MIM) capacitors.

13. The microelectronic device of claim 12, wherein the second devices comprise control logic devices including transistors partially vertically overlapping the semiconductor structure.

14. The microelectronic device of claim 11, further comprising:
a source structure vertically underlying the stack structure and coupled to the cell pillar structures; and
digit line structures vertically interposed between the first devices and the stack structure and coupled to the cell pillar structures; and
additional contact structures horizontally offset from the cell pillar structures and individually vertically extending completely through the stack structure and to the source structure.

15. The microelectronic device of claim 14, further comprising:
digit line contact structures vertically interposed between the first devices and the digit line structures and coupled to the digit line structures; and
conductive bond pad structures vertically interposed between the first devices and the digit line contact structures coupled to the digit line contact structures.

16. The microelectronic device of claim 11, further comprising:
conductive routing structures vertically overlying the second devices; and
conductive pad structures vertically overlying and coupled to at least some of the conductive routing structures.

17. The microelectronic device of claim 16, further comprising additional conductive contact structures coupled to some of the conductive routing structures and continuously vertically extending from positions vertically overlying at least some of the second devices to the stack structure.

18. A memory device, comprising:
a stack structure comprising tiers each comprising conductive material and insulative material vertically neighboring the conductive material;
strings of memory cells vertically extending through the stack structure;
a source structure vertically underlying the stack structure and coupled to the strings of memory cells; and
digit lines vertically overlying the stack structure and coupled to the strings of memory cells;
a semiconductor structure vertically overlying the digit lines;
capacitors partially vertically overlapping lowermost boundaries of the semiconductor structure;
control logic devices partially vertically overlapping uppermost boundaries of semiconductor structure and coupled to the strings of memory cells; and
conductive contact structures vertically extending through the semiconductor structure and coupling at least some the capacitors to some of the control logic devices.

19. The memory device of claim 18, further comprising conductive routing structures vertically overlying the control logic devices, one or more of the conductive routing structures coupled to one or more of the control logic devices, and one or more other of the conductive routing structures coupled to the source structure.

20. The memory device of claim 19, further comprising additional conductive contact structures coupling the source structure to the one or more other of the conductive routing structures, at least some of the additional conductive contact structures horizontally overlapping one another and vertically extending between the source structure and the one or more other of the conductive routing structures.
